(19) United States
(12) Patent Application Publication
(10) Pub. No.: US 2018/0108579 A1
(43) Pub. Date: Apr. 19, 2018

(54) SOLAR CELL EMITTER CHARACTERIZATION USING NON-CONTACT DOPANT CONCENTRATION AND MINORITY CARRIER LIFETIME MEASUREMENT

(71) Applicant: Aurora Solar Technologies (Canada) Inc., North Vancouver (CA)

(72) Inventor: Gordon Matthew DEANS, West Vancouver (CA)

(73) Assignees: Aurora Solar Technologies (Canada) Inc., North Vancouver, BC (CA); Aurora Solar Technologies (Canada) Inc., North Vancouver, BC (CA)

(21) Appl. No.: 15/737,235

(22) PCT Filed: Jun. 17, 2016
(86) PCT No.: PCT/CA2016/050709

§ 371 Date: Dec. 15, 2017

Related U.S. Application Data
(60) Provisional application No. 62/181,637, filed on Jun. 18, 2015.

(51) Int. Cl. H01L 21/66; H02S 50/10; H01L 31/068; H01L 31/18

(52) U.S. Cl. CPC H01L 22/14; H02S 50/10; H01L 31/1804; H01L 31/068; H01L 22/34

(57) ABSTRACT

A method and apparatus for estimating an effect of variations of wafer properties on operating parameters of photovoltaic cells during manufacturing is provided. Measurements of emitter sheet resistance, minority carrier lifetime, and wafer resistivity of a wafer are obtained during manufacture of the wafer into a photovoltaic cell. Measurements may be made in-line with manufacturing. Current and voltage (I-V) parameters of the photovoltaic cell, such as V_{OC}, I_{SC} and fill factor are estimated based on some the obtained measurements. Calculation routines for the I-V parameters may be monitored for accuracy and updated based on actual observed values of the I-V parameters as measured in the finished photovoltaic cells. The update may be based on a comparison between observed wafer properties and imputed wafer properties that are generated based on the observed values of the I-V parameters. The measurements and I-V parameters may be used to identify process faults.

### FIELD OF THE INVENTION

The present invention pertains to the field of photovoltaic production and quality control, and in particular to a method and apparatus for characterizing photovoltaic emitter properties such as dopant concentration and minority carrier lifetime in terms of their relationship to finished photovoltaic cell current and voltage parameters.

### BACKGROUND

The current and voltage (I-V) parameters used to grade solar (photovoltaic) cells by quality typically include open-circuit voltage (V_{OC}), short-circuit current (I_{SC}) and Fill Factor (FF). Current (I) is often expressed in normalized form as current density (J). V_{OC} and I_{SC} can be thought of as the maximum voltage and current of the solar cell respectively, while FF can be used in conjunction with V_{OC} and I_{SC} to determine the maximum power output of the solar cell.

M. Müller, G. Fischer, H. Wagner and P. P. Altermatt, “Understanding and reducing the variations in multicrystalline Si solar cell production,” in 28th European Photovoltaic Solar Energy Conference and Exhibition, Paris, France, 2013, describes the results of a study of the effect of variations in material and structural cell properties on finished cell efficiency. They indicated that the dominant parameters include silicon wafer minority carrier lifetime (τ), wafer interstitial oxygen concentration, wafer resistivity (ρ_{w}), the emitter saturation current density (J₀_{ₑ}), and contact resistivity (ρ_{c}). Other factors include the resistivity of the metal contacts themselves and the thickness of the anti-reflective and/or passivation coatings on the surfaces of the wafer. Variations in τ, ρ_{w}, ρ_{c} and J₀_{ₑ}, were indicated to collectively comprise approximately 78 percent of the influence on finished cell efficiency variations.

During solar cell manufacturing, emitter sheet resistance, minority carrier lifetime, wafer resistivity and the thickness of the anti-reflective and/or passivation coatings can be measured by off-line sampling and/or by continuous in-line instrumentation. For wafer resistivity, eddy current sensing as described in Semiconductor Equipment and Materials International, “SEMI MF673-1105 (Reapproved 0611)—Test Method for Measuring Resistivity of Semiconductor Wafers or Sheet Resistance of Semiconductor Films with a Noncontact Eddy-Current Gauge,” 2011, available at www.semi.org; infrared transmissivity as described in J. Isenberg, D. Biro and W. Warta, “Fast, Contactless and Spatially Resolved Measurement of Sheet Resistance by an Infrared Method,” Prog. Photovolt: Res. Appl., vol. 12, ρ. 539-552, 2004; or infrared reflectometry (IRR) as described in G. Deans, S. McDonald, C. Baer and K. Cadien, “Solar Wafer Emitter Measurement by Infrared Reflectometry for Process Control: Implementation and Results,” in 40th IEEE Photovoltaic Specialists Conference, Denver, Colo., USA, 2014 can be used. For emitter sheet resistance, infrared reflectometry (IRR) or surface/junction photovoltage (SPV/JPV) as described in D. Schroder, “Surface voltage and surface photovoltage: history, theory and applications,” Meas. Sci. Technol., vol. 12, pp. R16-R31, 2001 and Semilab Zrt., “CMS,” [Online]. Available: www.semilab.hu/products/pvi/cms can be used. For minority carrier lifetime, Quasi-Steady-State Photoconductance (QSSPC) as described in R. Sinton and A. Cuevas, “Contactless determination of current-voltage characteristics and minority-carrier lifetimes in semiconductors from quasi-steady-state photoconductance data,” Appl. Phys. Lett., vol. 69, no. 17, pp. 2510-2512, 1996; Carrier Density Imaging as described in J. Isenberg, S. Riepe, S. Glunz and W. Warta, “Imaging method for laterally resolved measurement of minority carrier densities and lifetimes: Measurement principle and first applications,” Journal of Applied Physics, vol. 93, no. 7, pp. 4268-4275, 2003; Photoluminescence as described in T. Trupke and e. al, “Progress with Luminescence Imaging for the Characterization of Silicon Wafers and Solar Cells,” in 22nd European Photovoltaic Solar Energy Conference, Milan, Italy, 2007; or Microwave Detected Photoconductivity (MDP), as described in K. Dornich, N. Schüler, D. Mittelstraß, A. Krause, B. Gründig-Wendrock, K. Niemietz, J. R. Niklas, “New Spatial Resolved Inline Lifetime Metrology on Multicrystalline Silicon for PV”, 24th European Photovoltaic Solar Energy Conference, 21-25 Sep. 2009, Hamburg, Germany, can be used.

In emitter sheet resistance measurement, U.S. Pat. No. 8,829,442 describes a system and method of non-contact measurement of the dopant content of semiconductor material by reflecting infrared (IR) radiation off of the material and splitting the radiation into two beams, passing each beam through pass band filters of differing wavelength ranges, comparing the level of energy passed through each filter and calculating the dopant content by referencing a correlation curve made up of known wafer dopant content for that system. U.S. Pat. No. 8,364,428 describes an alternative method.

However, the effective integration of measurement techniques such as those described above into a photovoltaic cell manufacturing process is not straightforward. There is a need for a method and apparatus for measuring properties of wafers and photovoltaic cells during a manufacturing process, and for using said measurements for manufacturing process control, that is not subject to one or more limitations of the prior art.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a method and apparatus for characterizing photovoltaic parameters such as dopant concentration and minority carrier lifetime. In accordance with an aspect of the present invention, there is provided a method for estimating an effect of variations of wafer properties on operating parameters of photovoltaic cells during manufacturing, the method comprising: obtaining, using one or more measurement devices, measurements of one or more properties of a wafer during manufacture of the wafer into a photovoltaic cell; and generating, using a processor, estimates of eventual (as exhibited by the photovoltaic cell after manufacture) current and voltage (I-V) parameters of the photovoltaic cell based at least in part on the obtained measurements.

In accordance with another aspect of the present invention, there is provided a method for estimating an effect of variations of wafer properties on operating parameters of photovoltaic cells, the method comprising: obtaining, using one or more measurement devices, measurements of one or more properties of a wafer during manufacture of the wafer into a photovoltaic cell; generating, using a processor, estimates of eventual current and voltage (I-V) parameters of the photovoltaic cell based at least in part on the obtained measurements; storing said estimates of I-V parameters in a database along with an identifier of the wafer; measuring I-V parameters of the photovoltaic cell following one or more manufacturing process steps performed after obtaining said measurements; upon determining a deviation of said measured I-V parameters for the wafer, or for a collection of wafers including the wafer, from an expected value or statistical distribution, initiating a fault investigation operation, comprising: retrieving information related to the wafer or the collection of wafers from the database, said information including said estimates of I-V parameters, said measurements, or a combination thereof; determining, based on an analysis of the retrieved information in association with stored data characterizing a set of known manufacturing faults, one or more potential manufacturing faults which are relatively more likely to have occurred; and outputting an indication of said one or more potential manufacturing faults.

In accordance with another aspect of the present invention, there is provided a method for estimating an effect of variations of wafer properties on operating parameters of photovoltaic cells, the method comprising: obtaining, using one or more measurement devices, observed values of one or more properties of each of a set of wafers during manufacture of each of the set of wafers into a corresponding photovoltaic cell; generating, using a processor, estimates of eventual current and voltage (I-V) parameters of the photovoltaic cells based at least in part on the observed values, the estimates generated using an estimation procedure; measuring, using an I-V tester, I-V parameters of the photovoltaic cells following manufacture; computing, for each of the photovoltaic cells, an imputed value of said one or more properties, the imputed value being determined such that, when the imputed value is input to said estimation procedure, the estimation procedure outputs a match to said measured I-V parameters; and adjusting, using the processor, the estimation procedure based at least in part on a comparison of said observed values and said imputed values.

In accordance with another aspect of the present invention, there is provided an apparatus for estimating an effect of variations of wafer properties on operating parameters of photovoltaic cells, the apparatus comprising: one or more measurement devices configured to obtain measurements of one or more properties of a wafer during manufacture of the wafer into a photovoltaic cell; and one or more processors operatively coupled to the one or more measurement devices and configured to generate estimates of eventual current and voltage (I-V) parameters of the photovoltaic cell, the estimates generated based at least in part on the obtained measurements.

In accordance with another aspect of the present invention, there is provided an apparatus for estimating an effect of variations of wafer properties on operating parameters of photovoltaic cells, the apparatus comprising: one or more measurement devices configured to obtain measurements of one or more properties of a wafer during manufacture of the wafer into a photovoltaic cell; one or more processors operatively coupled to the one or more measurement devices and configured to: generate estimates of eventual current and voltage (I-V) parameters of the photovoltaic cell, the estimates generated based at least in part on the obtained measurements; a database, wherein the one or more processors are configured to store, in the database, said estimates of I-V parameters along with an identifier of the wafer; an I-V cell tester configured, following one or more manufacturing process steps performed after obtaining said measurements, to measure I-V parameters of the photovoltaic cell manufactured from the wafer, and wherein the one or more processors are configured, upon determining a deviation, of said measured I-V parameters for the wafer or for a collection of wafers including the wafer, from an expected value or statistical distribution, to: retrieve information related to the wafer or the collection of wafers from the database, said information including said estimates of I-V parameters, said measurements, or a combination thereof; analyze the retrieved information in association with stored data characterizing a set of known manufacturing faults; determine, based on said analysis, one or more potential manufacturing faults which are relatively more likely to have occurred; and output an indication of said one or more potential manufacturing faults.

In accordance with another aspect of the present invention, there is provided an apparatus for estimating an effect of variations of wafer properties on operating parameters of photovoltaic cells, the apparatus comprising: one or more measurement devices configured to obtain observed values of one or more properties of each of a set of wafers during manufacture of each of the set of wafers into a corresponding photovoltaic cell; one or more processors operatively coupled to the one or more measurement devices and configured to: generate estimates of eventual current and voltage (I-V) parameters of the photovoltaic cells, the estimates generated based at least in part on the observed values, the estimates generated using an estimation procedure; an I-V cell tester configured, following one or more manufacturing process steps performed after obtaining said measurements, to measure I-V parameters of the photovoltaic cells manufactured from the wafers, wherein the one or more processors are further configured to: compute, for each of the photovoltaic cells, an imputed value, the imputed value being determined such that, when the imputed value is input to said estimation procedure, the estimation procedure outputs a match to said measured I-V parameters; and adjust the estimation procedure based at least in part on a comparison of said observed values and said imputed values.

### BRIEF DESCRIPTION OF THE FIGURES

FIG. 1 illustrates an apparatus provided in accordance with an embodiment of the present invention.

FIG. 2 illustrates a manufacturing process with measurement points, in accordance with an embodiment of the present invention.

FIG. 3 illustrates a process for estimating photovoltaic cell I-V parameters based on wafer measurements, in accordance with an embodiment of the present invention.

FIG. 4 illustrates a process for using estimated photovoltaic cell I-V parameters and for updating I-V parameter estimators, in accordance with an embodiment of the present invention.

### DETAILED DESCRIPTION OF THE INVENTION

Embodiments of the present invention provide for a method for combining measurements of wafer properties, such as minority carrier lifetime, emitter sheet resistance and/or wafer resistivity to yield an estimate of electrical (I-V) parameters of (finished) photovoltaic cells that are manufactured from the measured wafers. The I-V parameters of interest include open-circuit voltage (V_{OC}), short-circuit current (I_{SC}) or short-circuit current density (J_{SC}), and Fill Factor (FF). The estimates may be provided with a relatively high or low level of precision. In some embodiments, the estimates may be binned into a limited number of categories. For example, an estimate may indicate that a wafer is estimated to belong to one of a limited number of quality classes, such as “Class A”, “Class B”, or “Class C”, etc.

The I-V parameters of interest may be used to compute an indication of cell efficiency (η), which can be determined from the other parameters for example via the equation η=V_{OC}I_{SC}FF/Pᵢₙ, where Pᵢₙ is input power, for example determined as 100 mW/cm² as would be readily understood by a worker skilled in the art. The indication of cell efficiency may be an indication that the cell belongs to one of a limited number of categories. An associated apparatus is also provided. The wafer measurements may be non-contact type measurements, in which the measurement devices do not contact the wafer when measuring properties thereof. For example, the measurement devices may use light, electric fields and/or magnetic fields to measure wafer properties, and may also use light, electric fields and/or magnetic fields to induce a response related to certain properties in the wafer during measurements.

Embodiments of the present invention provide for a cost-effective and practical means to relate variations in wafer properties during manufacturing to expected finished cell parameters so that these properties can be controlled as necessary for improved manufacturing yield, and so that manufacturing process faults can be better detected and identified.

Embodiments of the present invention provide for the measurement of wafer properties at intermediate steps of the manufacturing process. The wafer properties can then be used to estimate the I-V parameters of one or more finished solar cells that are manufactured from the wafer. Multiple wafer properties may be measured during the same process step, and a limited number of properties may be measured and used to estimate the I-V parameters via particular relationships. The relationships may be predetermined and may be adjusted over time using manufacturing process feedback.

As used herein, measurement of a wafer property refers to the observation of the wafer property based on collected measurement data. A wafer property may be measured using a single device, or it may be measured using multiple devices operating in combination. Some wafer properties may be measured in part by calculation, by processing one or more measurement data points for the wafer in a predetermined manner, for example according to a mathematical model or function. Measurement values which are provided directly or through calculation can be collectively referred to as observed values.

According to embodiments of the present invention, one or more measurements of certain properties of a wafer (to be manufactured into a photovoltaic cell) are obtained using one or more measurement devices. Some or all of the measurement devices may be co-located and the measurements performed concurrently or sequentially. Additionally or alternatively, some or all of the measurement devices may be in different locations and used to measure wafers at different steps of the manufacturing process. The measurements are then used to compute the I-V parameters, for example using a computer, or a processor configured to perform computing operations.

The measurements may include a measurement of emitter sheet resistance Rₛₕₑₑₜ of the wafer. The emitter sheet resistance may be measured using an infrared reflectometry (IRR) measurement device or a surface/junction photovoltage (SPV/JPV) measurement device. Eddy current measurement devices may also be usable for measuring emitter sheet resistance.

The measurements may include a measurement of minority carrier lifetime of the wafer. The minority carrier lifetime may be measured using a quasi-steady-state photoconductance (QSSPC) measurement device, a photoluminescence (PL) measurement device, or microwave detected photoconductivity (MDP). Carrier density imaging devices may also be usable for measuring minority carrier lifetime.

When a PL device or an MDP device is used for minority carrier lifetime measurement, spatially resolved (across the lateral area of the wafer) data may be available. The spatially resolved data may indicate the minority carrier lifetime for a localized region of the wafer, as a function of the two-dimensional location on the wafer. The minority carrier lifetime can vary by wafer location for example due to an uneven distribution of chemical impurities or crystalline defects. If a QSSPC device is used, spatial resolution of the data may be limited or not available.

The measurements may include a measurement of overall resistivity of the wafer. Wafer resistivity can be measured using an eddy current probe. Alternatively, an infrared transmissivity or infrared reflectometry (IRR) measurement device may be used. Wafer resistivity may correspond, for example, to an averaged resistivity of a wafer at a substantially arbitrary manufacturing step.

In some cases, if a QSSPC measurement device is used, wafer resistivity measurements may also be available from the QSSPC measurement device. In this case, wafer resistivity and QSSPC measurements may be obtained from a single device.

The measurements may include a measurement of wafer thickness using a thickness gauge. Non-contact methods of measuring thickness may be used, for example based on capacitive methods. Various wafer thickness gauges may be used as would be readily understood by a worker skilled in the art. Wafer thickness can be related to other parameters such as emitter saturation current density and effective minority carrier lifetime for example as described in Equation (5) of “Contactless Carrier-Lifetime Measurements in Silicon Wafers, Ingots, and Blocks,” SEMI AUX017-0310, April, 2010, which is reproduced here as:

$$\frac{1}{{τ}_{eff} ( Δ n )} = \frac{1}{{τ}_{bulk} ( Δ n )} + \frac{{J}_{0 e front} + {J}_{0 e back}}{{qn}_{i}^{2} W} [ {N}_{A} + Δ n ]$$

Knowledge of wafer thickness can therefore be used in calculating emitter saturation current density from a minority carrier lifetime measurement.

Table 1 summarizes certain measurement devices and the measurements available therefrom. Other measurement devices not listed may also be available and used. Various embodiments of the present invention include a collection of measurement devices sufficient to obtain measurements of at least: minority carrier lifetime (τ); emitter sheet resistance (Rₛₕₑₑₜ); and wafer resistivity.

TABLE 1

| Measurement Device | Measurement Available |
|---|---|
| QSSPC device | Minority carrier lifetime (τ); Wafer resistivity ρ_{w} |
| PL device | Minority carrier lifetime (τ) |
| Carrier density imager | Minority carrier lifetime (τ) |
| Eddy current probe | Wafer resistivity |
| IRR device | Wafer resistivity; Emitter sheet resistance (Rₛₕₑₑₜ) |
| SPV/JPV device | Emitter sheet resistance (Rₛₕₑₑₜ) |
| MDP device | Minority carrier lifetime (τ) |
| Thickness gauge | Wafer thickness |

Examples of suitable collections of measurement devices include: an IRR device, wafer thickness gauge and a QSSPC device incorporating an eddy current probe; an IRR device, wafer thickness gauge a QSSPC device and a separate eddy current probe; an IRR device, wafer thickness gauge a PL device and an eddy current probe; and an MDP device, eddy current probe, wafer thickness gauge, and IRR device.

The computation of the estimated I-V parameters is performed based on given quantitative relationships between the obtained measurements and each of the I-V parameters.

A quantitative relationship may be provided as a set of computer instructions for calculating a value according to a given mathematical relationship. A quantitative relationship may be encoded into a lookup table, which returns a particular value for the I-V parameter based on the input measurement values.

It is noted herein that, while each I-V parameter is influenced by multiple material and structural properties in a solar cell, subsets of these properties tend to dominate each parameter, especially in a fixed manufacturing process that is operating under control, the term “control” meaning as understood by someone skilled in manufacturing engineering. For instance, V_{OC} is largely determined by the cell's saturation current density (J₀). In various embodiments, an estimate of V_{OC} is provided as a function of J₀_{ₑ} or as a function of both J₀_{ₑ} and Rₛₕₑₑₜ. FF is likewise largely determined by series resistance (Rₛ) and J₀. Rₛ is composed of emitter sheet resistance (Rₛₕₑₑₜ), wafer resistivity (ρ_{w}), contact resistivity (ρ_{c}) and the series resistance of the metal fingers and busbars. In various embodiments, an estimate of FF is provided as a function of Rₛₕₑₑₜ or as a function of both J₀_{ₑ} and Rₛₕₑₑₜ. J_{SC} is largely determined by J₀, although some correlation to resistivity may also occur. In various embodiments, an estimate of J_{SC} is provided as a function of Rₛₕₑₑₜ, J₀_{ₑ}, and measured wafer resistivity.

It is also noted that J₀ can be derived from the minority carrier lifetime τ at any process step prior to metallization, and that emitter saturation current density J₀_{ₑ} can likewise be calculated from Rₛₕₑₑₜ, τ and wafer thickness. Wafer resistivity ρ_{w} can be directly measured before emitter formation or, after emitter formation, calculated from Rₛₕₑₑₜ and the wafer's overall resistivity at this step.

Further, it is noted that interstitial oxygen is typically measured by infrared absorption during silicon ingot or wafer production, using Fourier Transform Interferometry (FTIR), for example as described in A. Hidenobu, I. Suzuki and H. Koya, “The Effect of Hydrogen Annealing on Oxygen Precipitation Behavior and Gate Oxide Integrity in Czochralski Si Wafers,” J. Electrochem. Soc., vol. 144, no. 1, pp. 306-310, 1997, and K. Krishnan, in Material Research Society Symposium Proceedings, 1983. Contact resistivity ρ_{c} is a function of the semiconductor-metal interface and therefore cannot be completely determined until metallization. However, in practice it can be relatively invariant unless metallization or emitter formation is not well controlled, the latter of which can be observed from Rₛₕₑₑₜ and J₀_{ₑ}.

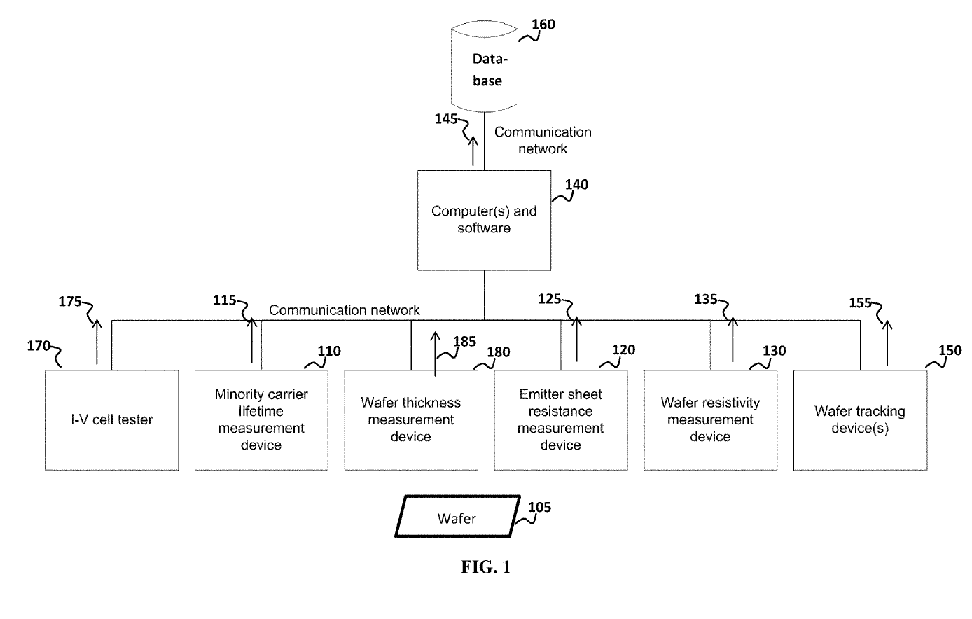

FIG. 1 illustrates an apparatus provided in accordance with an embodiment of the present invention. The apparatus includes a set of measurement devices 110, 120, 130, 180. Although four measurement devices are shown, more or fewer measurement devices can be provided. In particular, a single instrument can act as multiple measurement devices if it provides the appropriate measurement data. In the illustrated embodiment, the measurement devices include a minority carrier lifetime measurement device 110, an emitter sheet resistance measurement device 120, a wafer resistivity measurement device 130, and a wafer thickness gauge 180. At least some of the measurement devices may be co-located. In some embodiments, the measurement devices may be capable of interacting with the same wafer 105 concurrently. In other embodiments, some or all of the measurement devices are configured to interact with the same wafer 105 at different steps of the manufacturing process. In some embodiments, one or more measurement devices are configured to interact with the same wafer at multiple steps of the manufacturing process. In some embodiments, multiple instances of the same type of measurement device may be provided, each configured to interact with the same wafer at a different step of the manufacturing process.

For example, in some embodiments, carrier lifetime can be measured at multiple steps in the manufacturing process, for example after an emitter diffusion manufacturing process step, and then again after application of a passivation coating to the wafer.

In some embodiments, because different measurements can be provided by different instruments (possibly at different manufacturing steps), and because in some cases different measurements can be combined to calculate the observed value of a wafer property of interest, a virtual measurement device can be provided which obtains measurements from multiple physical measurement devices, processes the measurements using a computer directly or indirectly coupled to the measurement devices, and outputs the value of a property of interest.

In one embodiment, the minority carrier lifetime measurement device 110 is a QSSPC measurement device, a photoluminescence (PL) measurement device, a carrier density imaging device or an MDP measurement device. The emitter sheet resistance measurement device 120 may be an IRR measurement device or an SPV measurement device 120. The wafer resistivity measurement device 130 may be an eddy current probe. Optionally, the eddy current probe may be integrated with the QSSPC measurement device. Optionally, the second measurement device 120 for measuring wafer resistivity may also be the third measurement device 130 configured as an IRR measurement device. Other configurations are also possible, in which two or all three of the measurement devices are incorporated into a single measurement apparatus. A wafer 105 is subjected to non-contact interaction with and measurement by the measurement devices 110, 120, 130, 180.

The set of measurement devices 110, 120, 130,180 collectively provide a first measurement 115 indicative of minority carrier lifetime of a wafer, a second measurement 125 indicative of emitter sheet resistance of the wafer, a third measurement 135 indicative of wafer resistivity, and a fourth measurement 185 indicative of wafer thickness. In some embodiments, each measurement may be primarily or wholly provided by a single one of the measurement devices, for example device 110 may provide measurement 115, device 120 may provide measurement 125, and device 130 may provide measurement 135. Device 180 provides wafer thickness measurement 185. In some embodiments, a single measurement device may provide multiple ones of the measurements. In some embodiments, some measurements may be provided as a product of multiple measurement devices. For example, wafer thickness 185 may be used to assist in determining J₀_{ₑ}.

The first, second, third and fourth measurements 115, 125, 135, 185 are provided to a computer 140 or collection of computers. Each computer may include a microprocessor, microcontroller, or the like, operatively coupled to memory storing executable program instructions for carrying out processing operations as described herein. Each computer may be a stand-alone local or remote computer, or the computer may be embedded into instrumentation equipment. In some embodiments, the first, second, third and fourth measurements 115, 125, 135,185 are provided to a single computer. In other embodiments, multiple computers are provided, and at least two of the first, second, third and fourth measurements 115, 125, 135, 185 are provided to separate computers. The multiple computers then operate together to process the measurements.

The computer is configured, for example via executable program instructions stored in memory or via firmware configuration, or the like, to process the measurements 115, 125, 135, 185 to yield estimates 145 of some or all of the I-V parameters of interest.

Processing may involve numerical calculations, mathematical subroutines, value comparison operations, table lookup operations, execution of conditional logic statements, or the like, or a combination thereof. As an example, the measurements 115, 125, 135, 185 may be evaluated to determine which of a plurality of ranges they fall within. Based on the determined range, a corresponding processing routine for computing the estimates 145 of the I-V parameters V_{OC}, I_{SC} and FF may be selected. The processing routine may provide the estimates of V_{OC}, I_{SC} and FF as a function (such as, but not restricted to, a polynomial function) of the measurements 115, 125, 135, 185. The processing routines may be implemented by executing stored program instructions by a microprocessor operatively coupled to memory, or by firmware, application specific integrated circuits, field programmable gate arrays, or the like. The I-V parameters of each wafer are thereby estimated based on the obtained measurements.

In various embodiments, the apparatus further comprises at least one wafer-tracking device 150. This may be a barcode reader or a data matrix code reader configured to scan a barcode or data matrix marked on the wafer, or another type of scanner configured to determine a mark or characteristic of the wafer that can be used to uniquely identify the wafer. Alternatively, the wafer tracking device 150 may be configured to identify a batch to which the wafer belongs and a spatial or order location of the wafer within the batch, thereby identifying the wafer. As another alternative, the wafers can be tracked individually using manufacturing automation system capabilities. The wafer is accordingly associated with an identity 155. The computer 140 is configured, for example via stored program instructions executable by the microprocessor, to correlate the identity 155 of the wafer with the estimated I-V parameters 145 and/or measurements 115, 125, 135, 185. When measurements are obtained at multiple steps of the manufacturing process, multiple wafer tracking devices such as data matrix code readers may be provided for identifying the wafer at each step.

In various embodiments, the apparatus further comprises a database 160. The computer transmits the wafer identity 155 to the database for storage, along with the estimated I-V parameters 145 and/or the measurements 115, 125, 135, 185. Data can be retrieved from the database and used for classifying wafers or other quality control of manufacturing process monitoring and control operations.

In various embodiments, the apparatus further comprises an I-V cell tester 170. The I-V cell tester is located at a point where finished photovoltaic cells are tested and assigned a quality grade. The I-V cell tester may be separate from the measurement devices 110, 120, 130, 180 and tests the cells at a separate step of the manufacturing process. The I-V cell tester can store its measurements 175 of I-V parameters in the database 160 and/or the I-V cell tester can provide its measurements 175 of I-V parameters directly to the computer 140 or a different computer. Suitable I-V cell testers will be known to a worker skilled in the art. An I-V cell tester may, for example, electrically contact each finished photovoltaic cell, apply a range of voltage and current excitations, and measure corresponding electrical parameters. The cell is identified by a tracking device at the I-V cell tester location. The cell may have the same identifier as the wafer used to make the cell, or possibly a related identifier. Identification of the cell is performed so that the estimated I-V parameters previously generated for the cell or associated wafer can be retrieved from the database as described below.

The computer 140 or a different computer can access the database and compare the estimated I-V parameters 145 with the measurements of the I-V parameters 175 as provided by the I-V cell tester. The computer may also retrieve the measurements 115, 125, 135, 185 from the database, if available, and analyze them. The computer may then update one or more methodologies used by the computer 140 to process the measurements 115, 125, 135, 185 for providing the I-V parameters. This provides a feedback loop by which, when the estimated I-V parameters 145 differ from the final I-V parameters 175, the calculations used in generating the estimated I-V parameters 145 are adjusted to mitigate the difference. The adjustments may be performed periodically or on an ongoing basis.

Additionally, comparisons between the estimated I-V parameters and the measured I-V parameters may be used in monitoring the manufacturing process, for example by providing information indicative of process faults (also referred to as process excursions) within one or more manufacturing steps. For example, when the estimated I-V parameters for one or a collection of wafers are within manufacturing tolerances and are considered reliable, but the final measured I-V parameters for the corresponding solar cells are outside of manufacturing tolerances, a possible manufacturing fault at a process step after I-V parameter estimation may be indicated. The location of the fault may be identified, to at least some degree of precision, by the particular patterns of the estimated and measured I-V parameters, and/or other associated measurements.

In various embodiments, the nature of the discrepancies between estimated and measured I-V parameters and/or the between imputed and actual measured wafer properties, can be used to provide a statistical tool for identifying manufacturing process faults and/or determining the location and nature of such faults. To build a database, known manufacturing faults can be artificially induced, or possibly identified as they occur through other means. The known manufacturing faults may correspond to particular failure modes of particular manufacturing equipment or personnel, for example. For wafers processed during each known fault, the estimated and measured I-V parameters for those wafers can be stored, possibly along with other wafer measurements, in association with an identification of the fault. The estimated I-V parameters and/or other wafer measurements may correspond to estimates and/or measurements that are obtained at one or possibly multiple steps in the manufacturing process. If a parameter or measurement is obtained at multiple steps, it may be stored along with an indication of the step at which it was obtained. The stored data (I-V parameters and measurements for typically multiple wafers) associated with each fault is referred to herein as the fault characteristic data.

Known faults may correspond to single points of failure, for example in but not limited to the failure of a heating element in a thermal oven, a chemical coating deposition machine or a metal paste printing machine. Alternatively, known faults may correspond to combinations of multiple points of failure.

When a manufacturing fault is initially unknown but determined later upon investigation, the property measurements and I-V parameters of wafers which were manufactured during the fault event can be identified. The associated property measurements and I-V parameters of such wafers can be accessed in the database and marked as being fault characteristic data, along with an indication of the identified fault. In this manner, the fault database can be made to grow over time and to incorporate faults occurring during ongoing manufacturing.

When, upon I-V testing, an individual solar cell or collection of solar cells fails to exhibit an expected range of parameters, a fault investigation operation may be triggered, for example automatically. The fault investigation operation may be carried out by a computer. During fault investigation, the measured I-V parameters for the solar cells, along with the estimated I-V parameters and/or underlying measurements of the associated wafers can be obtained from the database and statistically analyzed. This data is referred to herein as the data under investigation. The analysis is configured to determine which set of fault characteristic data more closely matches the data under investigation. A computer may be configured to perform this analysis based on a predetermined statistical method, pattern matching method, or the like. When one or more close matches between fault characteristic data and data under investigation are found, the known faults associated with the matching fault characteristic data are returned as potential faults occurring in the present investigation operation.

In some embodiments, when multiple potential faults are returned, they may be presented along with an indication of likelihood that each fault has occurred. Likelihood can be determined based on factors such as: closeness of match between fault characteristic data and data under investigation, expected frequency of occurrence of known faults, prior maintenance information, and the like.

### I-V Parameter Estimation

Embodiments of the present invention may be used to provide I-V parameter estimates for photovoltaic wafers undergoing manufacturing. The wafers may be manufactured using a particular recipe, for example specifying the particulars of manufacturing process steps and constituent components. In some embodiments, the I-V parameter estimates may be generated in a manner that is specific to the recipe being used, or to a group of recipes.

In one embodiment, when the I-V parameter is V_{OC}, the functional relationship between V_{OC} and the measurements corresponds to V_{OC} being estimated directly from J₀_{ₑ}, using the equation for implied V_{OC} as described in R. Sinton and A. Cuevas, “Contactless determination of current-voltage characteristics and minority-carrier lifetimes in semiconductors from quasi-steady-state photoconductance data,” Appl. Phys. Lett., vol. 69, no. 17, pp. 2510-2512, 1996. In one embodiment, Implied V_{OC} can be estimated using the relationship set forth in Equation (2) of “Implied-V_{OC} and Suns-V_{OC} Measurements in Multicrystalline Solar Cells,” by S. Bowden, V. Yelundur and A. Rohatgi, IEEE 29^{th} Photovoltaic Specialists Conference, May 2002. This equation is reproduced below as:

$$Implied {V}_{OC} = \frac{kT}{q} ln ( \frac{{nN}_{A}}{{n}_{i}^{2}} ) .$$

Here, n is minority carrier concentration at the junction edge, nᵢ is intrinsic carrier concentration, N_{A} is base doping, and kT/q is thermal voltage.

In one embodiment, when the I-V parameter is V_{OC}, the functional relationship between V_{OC} and the measurements corresponds to V_{OC} being estimated as a function of J₀_{ₑ}, and Rₛₕₑₑₜ. This may be motivated by the observation that V_{OC} may be affected by changes in shunt resistance (Rₛₕ) at high out-of specification Rₛₕₑₑₜ values.

In one embodiment, when the I-V parameter is J_{SC}, the functional relationship between J_{SC} and the measurements corresponds to J_{SC} being estimated as a function (such as but not restricted to a polynomial function) of Rₛₕₑₑₜ, J₀_{ₑ} and wafer resistivity.

In one embodiment, when the I-V parameter is FF, the functional relationship between FF and the measurements corresponds to FF being estimated as a function (such as a linear function) of Rₛₕₑₑₜ.

In one embodiment, when the I-V parameter is FF, the functional relationship between FF and the measurements corresponds to FF being estimated as a function (such as a linear function) of both Rₛₕₑₑₜ and J₀_{ₑ}. This may be motivated by the observation that the dependence of FF on Rₛₕₑₑₜ can be complicated by low or high J₀_{ₑ}, and that, additionally, the relationship to Rₛₕₑₑₜ may become higher-order at high out-of specification Rₛₕₑₑₜ values due to lowered Rₛₕ and/or higher ρ_{c}.

In various embodiments, the functional relationships used to estimate I-V parameters based on obtained measurements can be determined experimentally. For example, values in lookup tables can be determined experimentally, as can the coefficients of polynomials or other functions describing and implementing the functional relationships. More generally, the computations used in estimating the I-V parameters can be adjusted. Given a particular wafer recipe and manufacturing process, a sample of wafers and/or finished solar cells can be subjected to the measurements as described above and also extensively tested to determine the corresponding estimated and actual I-V parameters of the finished cell. Through statistical analysis, curve fitting, interpolation, extrapolation, and the like, a functional relationship between the measurements and I-V parameters can be derived. The functional relationship can be determined fully empirically or based at least in part on theoretical models. In various embodiments, the functional relationships can be updated in an ongoing manner by measuring I-V parameters of finished products for which wafer measurements have been obtained, and adjusting the functional relationships according to the I-V parameter and wafer measurement information.

### Manufacturing and Wafer Quality Tracking Details

In various embodiments, the solar cell wafer being measured may be identified, and the computed I-V parameters related to that solar cell wafer may be stored in association with the wafer's identity as part of a manufacturing quality control and tracking process.

Embodiments of the present invention may be used during manufacturing to monitor the effect of variations of key wafer properties and controlling these variations to achieve consistent, targeted I-V parameters, for a particular established cell design.

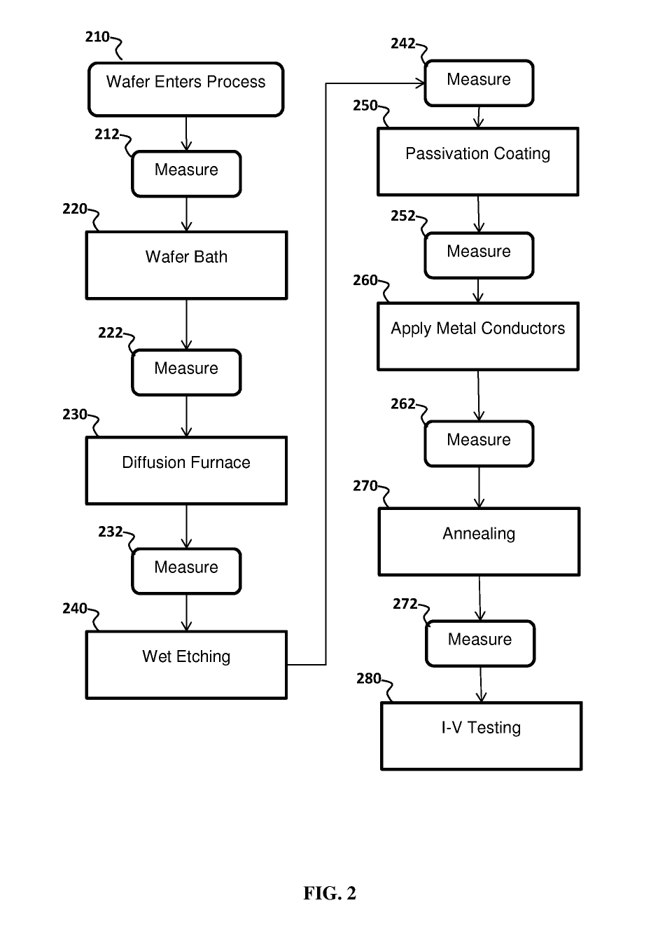

FIG. 2 illustrates an example manufacturing process according to an embodiment of the present invention. It should be noted that the manufacturing process can be varied in many ways, and this process is illustrative only. Some or all of the process steps may be applied to batches of wafers. A wafer enters 210 the manufacturing process and is subjected to a bath 220 to prepare the wafer. The wafer then enters a diffusion furnace 230 that assists in forming the emitter. The wafer then undergoes wet etching 240 to remove surface by-products. The wafer then undergoes one or more passivation coating 250 steps. The wafer then undergoes the application of metal conductors 260 on the front and back of the wafer, often using a screen-printing process. The wafer then undergoes annealing 270 in a co-firing furnace to anneal the metal conductors and condition the coatings. The wafer then undergoes I-V testing 280.

FIG. 2 further illustrates a plurality of locations in the manufacturing process at which wafer measurements as described herein can potentially be made. Embodiments of the present invention comprise performing wafer measurements at one, some, or all of these locations. The locations occur before and after each process step, and are marked as 202, 212, 222, 232, 242, 252, 262, and 272.

Measurements may be made at a location for which use of a particular measurement device will yield an indication of the value of a certain property of the wafer. Measurements may be made at a location for which a property value can be determined reliably. Measurements of certain properties may be made at multiple different steps. This allows one to combine the measurements for improved accuracy and/or to monitor for faults due to mismatched measurements.

In some embodiments, measurements of emitter sheet resistance may be obtained, without obtaining measurements of minority carrier lifetime. In other embodiments, measurements of both emitter sheet resistance and minority carrier lifetime may be made. Omitting one or more measurements such as minority carrier lifetime may reduce the amount of information available throughout the manufacturing process, however information is still provided by the other obtained measurements.

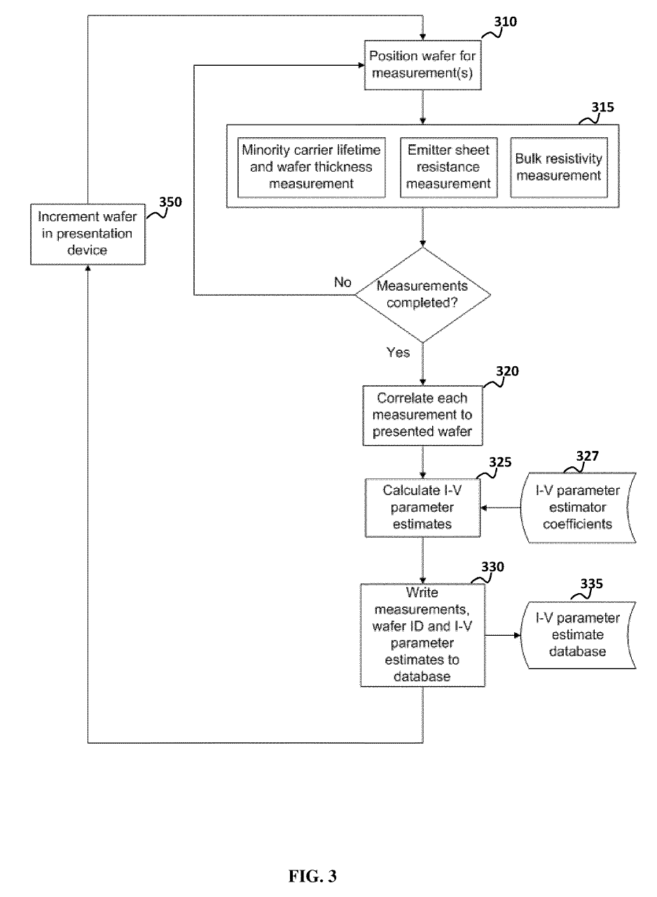

According to a part of the manufacturing process, and as illustrated in FIG. 3, the wafer is positioned 310 for measurement. Subsequently, one, some or all of emitter sheet resistance, wafer resistivity, minority carrier lifetime and wafer thickness are measured 315 in the same wafer simultaneously or in any order. Wafers are tracked to ensure these measurements are correlated 320 to the correct (same) wafer.

As described above, the measured wafer properties are entered into an estimator that calculates 325 estimates of the following solar cell I-V parameters: Open-circuit voltage (V_{OC}); Short-circuit current (I_{SC}); and Fill factor (FF). From these estimated electrical parameters above, the estimated cell efficiency (ii) can be calculated. The calculations 325 for the I-V parameter estimates may be based on stored I-V parameter estimator coefficients stored in a database 327. The coefficients may be polynomial coefficients for mathematical relationships used for determining I-V parameters, for example. The coefficients may be fixed or updatable based on process feedback. The estimates and wafer identity are then stored 330 in a database 335. The next wafer can then be presented 350 for measurement.

The process illustrated in FIG. 3 can be carried out multiple times during multiple manufacturing steps. That is, during various steps of preparation of the wafer into a solar cell, one, some, or all of the measurements necessary for determining cell I-V parameters may be obtained. The estimator may calculate 325 the estimates at a time when all of the necessary measurements have been made. The estimator may calculate multiple estimates based on measurements made at different steps.

In various embodiments, spatially resolved estimated parameters are made either by direct calculation at local measurements (in the case of PL or MDP), or by assuming carrier lifetime is uniform throughout the wafer (in the case of QSSPC).

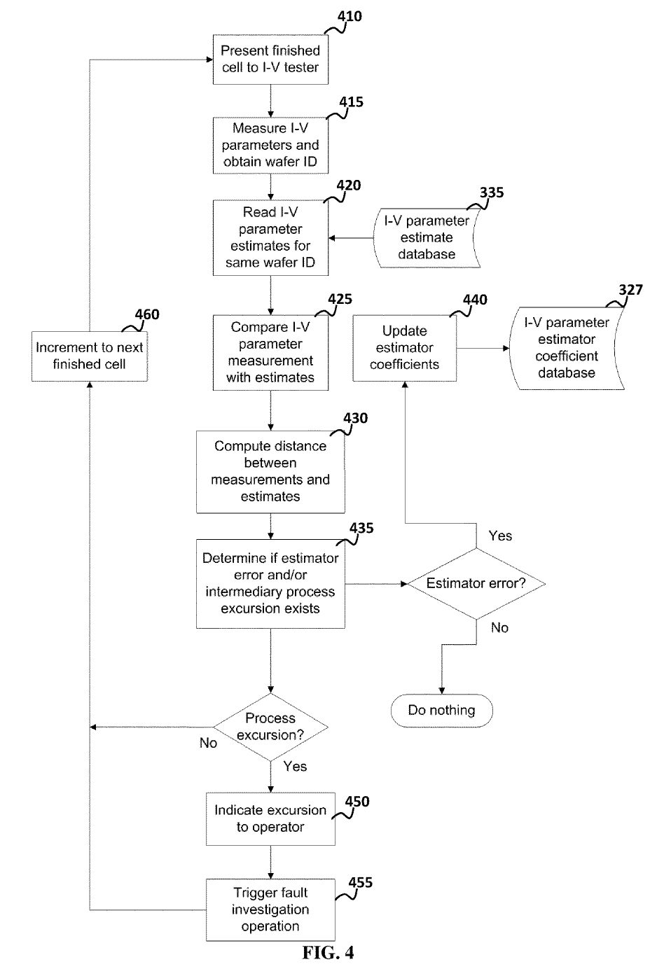

In various embodiments, as mentioned above, the computations used for estimating the I-V parameters can be adjusted based on obtained information stored in the database. FIG. 4 illustrates a process for adjusting the computations according to an embodiment of the present invention. A finished solar cell is presented 410 to the I-V cell tester following manufacturing. I-V tests are conducted on the solar cell 415 to obtain the I-V parameters thereof, and the wafer ID is also obtained. The estimated I-V parameters for the wafer ID are read 420 from the database 335. The results of the I-V tests on the solar cell are compared 425 to the I-V parameter estimates for the solar cell. The error, that is the distance (difference) between I-V parameter measurements and their estimates, is computed 430. A determination 435 is made whether differences (if present) in the comparisons are indicative of an intermediary process fault (for example a problem with passivation coating operation) and/or are indicative of a need to update one or more of the I-V parameter estimation procedures, for example by updating model coefficients used in the procedures. If an estimator error is detected, I-V parameter estimation coefficients (or procedures) are updated 440 in the database 327. If a process fault is detected, the fault can be indicated 450 to an operator. A fault investigation operation may also be triggered 455. The next solar cell is presented 460 for I-V parameter measurement and the process repeats.

As described herein, a set of measurements are performed on a wafer to determine certain properties of the wafer, such as emitter sheet resistance, minority carrier lifetime, thickness, and wafer resistivity. As also described herein, I-V parameters can be estimated from the measured properties. The procedure for estimating I-V parameters from measured properties can be regarded as mapping measured or calculated property values to I-V parameters using a mapping function ƒ. An estimator performs computing operations which correspond to implementation of the mapping function. The estimator may be a computer or functionality of a computer, as provided for example by executing stored program instructions by a microprocessor. For ease of discussion, the set of measured or calculated property values will be termed “observed” values, and they can be represented by a vector value \vec{m} in an n-dimensional vector space, where n is the number of discrete properties observed for each wafer, such values being determined prior to actual I-V parameter measurements of the solar cell resulting from processing of the wafer. The estimated I-V parameters for a wafer can be represented by a value Pₑₛₜ=ƒ(\vec{m}).

Furthermore, an inverse mapping or approximate inverse mapping, represented for purposes of discussion by a function ƒ⁻¹, can be performed on the actual I-V parameter values of a finished cell to determine values for the wafer properties that the estimator would have expected to have had as input to yield those actual I-V parameter values for that cell. For ease of discussion, we will term these latter wafer property values “imputed” values. The inverse mapping is defined so that ƒ⁻¹(ƒ(\vec{m}))≈\vec{m}. In various embodiments, after a solar cell undergoes I-V testing, the actual I-V parameters, represented herein by value Pₘₑₐₛ and measured using an I-V tester, can be subjected to the inverse mapping to determine the imputed values \vec{z} for the properties that would have yielded the I-V parameters Pₘₑₐₛ. This can be regarded as computing \vec{z}=ƒ⁻¹(Pₘₑₐₛ). The value Pₘₑₐₛ may have multiple components, and may be represented as a vector or set.

It is noted that there may not necessarily be a unique set of imputed values, but that techniques known to those skilled in the art can be used to mitigate this issue. For example, calculation of least mean-squared error using iterative methods, combined with knowledge of the relative accuracy of the various property measurements, can be used to determine an appropriate set of imputed values.

In various embodiments, therefore, for each wafer the observed property values \vec{m} are stored in the database, and the imputed property values \vec{z} are computed for the solar cell which is manufactured from the wafer, based on the I-V parameters obtained during I-V testing. For that wafer, the estimator can determine the value of an error vector \vec{err}=\vec{m}-\vec{z}, where \vec{m} and \vec{z} are both n-dimensional vector quantities. The error vector can be stored in the database. Error vectors can be determined and stored for a plurality of wafers, and potentially all wafers, or at least a significant selection of wafers.

In some embodiments, instead of storing individual error vectors separately, the error vectors can be used to update a cumulative representation of multiple error vectors. For example, the cumulative representation may track a moving set of observed error vectors.

When the estimator is accurate, the estimated I-V parameters should correspond closely with the actual measured I-V parameters, and it follows that the error vectors should be close to zero. However, it is also possible that the estimator is inaccurate, in which case the error vectors may be non-zero. Therefore, embodiments of the present invention are configured to adjust the estimator being used, based on observed error values.

In some embodiments, the error values (which may be vector values) for a plurality of wafers/cells are determined based on measurements of wafer properties, measurements of the I-V parameters of the corresponding finished solar cells, and a predetermined estimator being evaluated. The error values may then be stored in a database. Statistical methods can be applied to the determined error values for the plurality of wafers, in order to discern statistically significant patterns or trends in the error values. When a pattern or trend of non-zero error values is detected, the estimator may be adjusted in a manner that tends to mitigate the error values.

For example, a new estimator (represented as a function g to be used in place of ƒ) may be determined, which tends to give smaller error values than the current estimator, at least when applied to the already-collected data. The new estimator may be determined using various computational techniques, such as but not limited to least mean squares techniques.

In some embodiments, the estimator may be adjusted based at least in part on the difference between estimated and measured I-V parameters, instead of, or in addition to, the difference between measured properties and values of properties which would have resulted in the measured I-V parameters.

In some embodiments, the estimator procedure is represented by the function ƒ, and the parameters or coefficients of the function ƒ (for example a polynomial) can be referred to as the estimator coefficients. In some embodiments, adjusting the estimator comprises adjusting the estimator coefficients. The new estimator may be determined from the current estimator, for example by adjusting the estimator coefficients by a predetermined amount. Alternatively, the new estimator may be determined without regard to the current estimator. Adjusting an estimator may refer to either determining the new estimator based on a change to the current estimator, or to generating a new estimator without regard to the current estimator.

In some embodiments, sets of error vectors may be distributed about a central point representing a mean of the error vectors. The distribution of error vectors about the mean can be characterized by a variance. The variance can be due for noise, for example including measurement error and variations in unmeasured properties and latent (not directly measurable) properties. A limited amount of noise is typically expected. If a set of error vectors exhibits statistical stationarity, the processes and raw material may be deemed to be under control. Desirably, sets of error vectors may be tightly distributed around their mean, in which case there is limited noise and the measured properties exhibit limited variation.

If a set of error vectors does not exhibit sufficient statistical stationarity a problem may be deemed to exist. The problem may be a process drift, process fault, and/or the presence of unmeasured or latent properties that are changing with sufficient significance that they should ideally be included in the measured or calculated properties. The nature of the changes exhibited in the set of error vectors may be analyzed to determine potential causes of the non-stationarity.

### Example Embodiment

In an example embodiment, emitter sheet resistance is measured by an infrared detection technique such as described in U.S. Pat. No. 8,829,442 and/or International Patent Application Publication No. WO 2016/029321 A1, both of which are hereby incorporated by reference, while the minority carrier lifetime is measured by a QSSPC technique, an MDP technique or a PL technique. Eddy current measurements are obtained either by the QSSPC device, or by a separate eddy current measurement device. The measurement devices are located adjacent to each other and wafer tracking is used to correlate the obtained measurements to the wafers being measured.

Each measurement device is connected to a common computer by, for example, an Ethernet-based communication network. The computer is programmed to receive the measurements form the measurement devices and determine I-V parameter estimates based on them.

The data generated by the computer, including the I-V parameter estimates, are stored in a database. Maps of all data can be displayed, spatially resolved and linked to one or more preceding production tool's wafer distribution and batch history, for example as described in International Patent Application Publication No. WO 2016/061671.

Embodiments of the present invention provide for continuous, in-line instrumentation for use in a photovoltaic manufacturing process. Such instrumentation is integrated into the manufacturing process itself for continuous wafer monitoring. For example, wafer measurement instrumentation may be used to test wafers partway through their manufacture and between other manufacturing steps. This approach may provide a means to accurately track and control process variations. Accordingly, the instrumentation may be desirably non-destructive, fast enough to measure wafers at full production rates, and operable without requiring contact with wafers, thereby mitigating yield loss due to damage or contamination. Furthermore, for the purposes of control and rapid fault detection and correction, measurements may be made at certain critical intermediary cell production process steps. Such process steps may include, but are not limited to, incoming wafer inspection, emitter formation and passivation coating application.

Embodiments of the present invention may be used in the estimation of cell electrical parameters. Such estimates can be used to sort or reject wafers prior to further processing or adding further value.

Embodiments of the present invention may be used to provide a mapping of dopant content, J₀_{ₑ} and wafer resistivity, or other parameters such as calculated wafer efficiency, to wafer locations in a furnace. Mapping of data to wafer locations in a furnace may be performed for example as described in International Patent Application Publication No. WO 2016/061671, which is hereby incorporated by reference. Such an approach may be used to generate data to diagnose causes of manufacturing variations, and to direct corrective actions.

Embodiments of the present invention may be used to determine the impact of emitter formation variations on wafer performance, for example FF.

Embodiments of the present invention may be used to determine an indication of raw wafer resistivity without prior measurement of this property.

Embodiments of the present invention may be used to narrow down variations or faults in front/rear passivation or metallization manufacturing steps that affect I-V parameters.

When combined with correlation of wafer results at the finished cell tester, embodiments of the present invention may be used to provide rapid diagnostics/analysis of the production line impact of wafer (resistivity and bulk lifetime) and process (emitter J₀_{ₑ} and emitter sheet resistance), and of the impact of these factors on I-V parameters.

It will be appreciated that, although specific embodiments of the technology have been described herein for purposes of illustration, various modifications may be made without departing from the spirit and scope of the technology. In particular, it is within the scope of the technology to provide a computer program product or program element, or a program storage or memory device such as a magnetic or optical wire, tape or disc, or the like, for storing signals readable by a machine, for controlling the operation of a computer according to the method of the technology and/or to structure some or all of its components in accordance with the system of the technology.

Acts associated with the method described herein can be implemented as coded instructions in a computer program product. In other words, the computer program product is a computer-readable medium upon which software code is recorded to execute the method when the computer program product is loaded into memory and executed on the microprocessor of the wireless communication device.

Further, each step of the method may be executed on an electronic device, such as a computer, and pursuant to one or more, or a part of one or more, program elements, modules or objects generated from any programming language, such as C++, Java, or the like. In addition, each step, or a file or object or the like implementing each said step, may be executed by special purpose hardware or a circuit module designed for that purpose.

It is obvious that the foregoing embodiments of the invention are examples and can be varied in many ways. Such present or future variations are not to be regarded as a departure from the spirit and scope of the invention, and all such modifications as would be obvious to one skilled in the art are intended to be included within the scope of the following claims.

What is claimed is:

1. A method for estimating an effect of variations of wafer properties on operating parameters of photovoltaic cells, the method comprising:
obtaining, using one or more measurement devices, measurements of one or more properties of a wafer during manufacture of the wafer into a photovoltaic cell; and
generating, using a processor, estimates of eventual current and voltage (I-V) parameters of the photovoltaic cell based at least in part on the obtained measurements.

2. The method of claim 1, wherein said estimates of current and voltage (I-V) parameters are generated based on one or more quantitative relationships, the method further comprising:
storing said estimates of I-V parameters along with an identifier of the wafer;
measuring I-V parameters of the photovoltaic cell following one or more manufacturing process steps performed after obtaining said measurements;
adjusting the one or more quantitative relationships based on one or both of: a comparison of said estimates of I-V parameters and said measured I-V parameters; and a comparison of said measurements and imputed wafer property values derived from said measured I-V parameters using an inverse of the one or more quantitative relationships.

3. The method of claim 1, wherein the properties include one or more of: emitter sheet resistance, minority carrier lifetime, wafer thickness, and wafer resistivity.

4. The method of claim 3, wherein at least two of: emitter sheet resistance, minority carrier lifetime, wafer thickness, and wafer resistivity are measured during the same process step in a manufacturing process for providing the photovoltaic cells.

5. The method of claim 3, wherein at least two of: emitter sheet resistance, minority carrier lifetime, wafer thickness, and wafer resistivity are measured at different steps in a manufacturing process for providing the photovoltaic cells.

6. The method of claim 3, wherein a Quasi-Steady-State Photoconductance (QSSPC) device is used for measuring minority carrier lifetime, the QSSPC device further providing eddy current measurements, wherein one or both of emitter sheet resistance and wafer resistivity are based at least in part on said eddy current measurements.

7. The method of claim 3, wherein emitter sheet resistance is measured using an infrared reflectometry (IRR) measurement device or a surface/junction photovoltage (SPV/JPV) measurement device.

8. The method of claim 3, wherein minority carrier lifetime is measured using a Quasi-Steady-State Photoconductance (QSSPC) measurement device, a photoluminescence (PL) measurement device, a microwave detected photoconductivity (MDP) device, or a carrier density imaging device.

9. The method of claim 3, wherein wafer resistivity is measured using an eddy current probe or an infrared transmissivity or infrared reflectometry (IRR) measurement device.

10. The method of claim 3, wherein said at least one of the I-V parameters includes open-circuit voltage (V_{OC}), and wherein V_{OC} is determined based on either: emitter saturation current density (J₀_{ₑ}); or a combination of J₀_{ₑ} and the emitter sheet resistance, wherein J₀_{ₑ} is determined based on the emitter sheet resistance, the minority carrier lifetime, and the wafer thickness.

11. The method of claim 3, wherein the at least one of the I-V parameters includes short-circuit current (I_{SC}) or short-circuit current density (J_{SC}), and wherein I_{SC} or J_{SC} is determined based on saturation current density (J₀), the emitter sheet resistance, and wafer resistivity, wherein J₀ is determined based on the wafer resistivity and the minority carrier lifetime, and wherein wafer resistivity is either measured directly or determined based on emitter sheet resistance and overall wafer resistivity.

12. The method of claim 3, wherein the at least one of the I-V parameters includes fill factor (FF), and wherein FF is determined based on either: the emitter sheet resistance; or a combination of the emitter sheet resistance with either: saturation current density (J₀) or emitter saturation current density (J₀_{ₑ}), wherein J₀ is determined based on the wafer resistivity and the minority carrier lifetime, and J₀_{ₑ} is determined based on the emitter sheet resistance and the minority carrier lifetime.

13. The method of claim 1, wherein the one or more measurement devices are provided in-line with a manufacturing process for providing the photovoltaic cells.

14. The method of claim 1, wherein the one or more measurement devices consist of one of the following arrangements: one or more infrared transmissivity or infrared reflectometry (IRR) measurement devices, one or more wafer thickness gauges and one or more QSSPC devices incorporating an eddy current probe; one or more IRR devices, one or more wafer thickness gauges, one or more QSSPC devices and one or more separate eddy current probes; one or more IRR devices, one or more wafer thickness gauges, one or more photoluminescence (PL) measurement devices and one or more eddy current probes; or one or more microwave detected photoconductivity (MDP) devices, one or more wafer thickness gauges, one or more eddy current probes, and one or more IRR devices.

15. A method for estimating an effect of variations of wafer properties on operating parameters of photovoltaic cells, the method comprising:
obtaining, using one or more measurement devices, measurements of one or more properties of a wafer during manufacture of the wafer into a photovoltaic cell;
generating, using a processor, estimates of eventual current and voltage (I-V) parameters of the photovoltaic cell based at least in part on the obtained measurements;
storing said estimates of I-V parameters in a database along with an identifier of the wafer;
measuring I-V parameters of the photovoltaic cell following one or more manufacturing process steps performed after obtaining said measurements;
upon determining a deviation of said measured I-V parameters for the wafer, or for a collection of wafers including the wafer, from an expected value or statistical distribution, initiating a fault investigation operation, comprising:
retrieving information related to the wafer or the collection of wafers from the database, said information including said estimates of I-V parameters, said measurements, or a combination thereof;
determining, based on an analysis of the retrieved information in association with stored data characterizing a set of known manufacturing faults, one or more potential manufacturing faults which are relatively more likely to have occurred; and
outputting an indication of said one or more potential manufacturing faults.

16. A method for estimating an effect of variations of wafer properties on operating parameters of photovoltaic cells, the method comprising:
obtaining, using one or more measurement devices, observed values of one or more properties of each of a set of wafers during manufacture of each of the set of wafers into a corresponding photovoltaic cell;
generating, using a processor, estimates of eventual current and voltage (I-V) parameters of the photovoltaic cells based at least in part on the observed values, the estimates generated using an estimation procedure;
measuring, using an I-V tester, I-V parameters of the photovoltaic cells following manufacture;
computing, for each of the photovoltaic cells, an imputed value of said one or more properties, the imputed value being determined such that, when the imputed value is input to said estimation procedure, the estimation procedure outputs a match to said measured I-V parameters; and
adjusting, using the processor, the estimation procedure based at least in part on a comparison of said observed values and said imputed values.

17. The method of claim 16, wherein said properties comprise one or more of: emitter sheet resistance, minority carrier lifetime, thickness, and wafer resistivity.

18. The method of claim 16, wherein the comparison of said observed values and said imputed values comprises determining error vectors each being equal to a vector difference between one of said observed values and a corresponding one of said imputed values.

19. The method of claim 18, wherein the estimation procedure is adjusted based on the error vectors.

20. The method of claim 16, wherein the estimation procedure is adjusted based on a cumulative representation of multiple error vectors, each error vector being equal to a vector difference between one of said observed values and a corresponding one of said imputed values.

21. An apparatus for estimating an effect of variations of wafer properties on operating parameters of photovoltaic cells, the apparatus comprising:
one or more measurement devices configured to obtain measurements of one or more properties of a wafer during manufacture of the wafer into a photovoltaic cell; and
one or more processors operatively coupled to the one or more measurement devices and configured to generate estimates of eventual current and voltage (I-V) parameters of the photovoltaic cell, the estimates generated based at least in part on the obtained measurements.

22. The apparatus of claim 21, wherein the one or more processors generate said estimates of current and voltage (I-V) parameters based on one or more quantitative relationships, the apparatus further comprising a database and an I-V cell tester, and wherein:
the one or more processors are configured to store, in the database, said estimates of I-V parameters along with an identifier of the wafer;
the I-V cell tester is configured, following one or more manufacturing process steps performed after obtaining said measurements, to measure I-V parameters of the photovoltaic cell manufactured from the wafer;
the one or more processors are configured to adjust the one or more quantitative relationships based on one or both of: a comparison of said estimates of I-V parameters and said measured I-V parameters; and a comparison of said measurements and imputed values derived from said measured I-V parameters using an inverse of the one or more quantitative relationships.

23. The apparatus of claim 21, wherein the properties include one or more of: emitter sheet resistance, minority carrier lifetime, thickness, and wafer resistivity.

24. The apparatus of claim 23, wherein the one or more measurement devices are configured to obtain at least two of said measurements of emitter sheet resistance, minority carrier lifetime, and wafer resistivity during the same process step in a manufacturing process for providing the photovoltaic cells.

25. The apparatus of claim 23, wherein at least two of: emitter sheet resistance, minority carrier lifetime, thickness, and wafer resistivity are measured at different manufacturing process steps.

26. The apparatus of claim 23, wherein the one or more measurement devices includes an infrared reflectometry (IRR) measurement device or a surface/junction photovoltage (SPV/JPV) measurement device, and wherein said IRR measurement device or SPV/JPV measurement device is configured to measure emitter sheet resistance.

27. The apparatus of claim 23, wherein the one or more measurement devices includes a Quasi-Steady-State Photoconductance (QSSPC) measurement device, a photoluminescence (PL) measurement device, a microwave detected photoconductivity (MDP) device, or a carrier density imaging device, wherein said QSSPC measurement device, PL measurement device, MDP device or carrier density imaging device is configured to measure minority carrier lifetime.

28. The apparatus of claim 23, wherein the one or more measurement devices includes an eddy current probe or an infrared transmissivity or infrared reflectometry (IRR) measurement device, said eddy current probe, infrared transmissivity or IRR measurement device configured to measure wafer resistivity.

29. The apparatus of claim 23, wherein said at least one of the I-V parameters includes open-circuit voltage (V_{OC}), and wherein the one or more processors are configured to determine V_{OC} based on either: emitter saturation current density (J₀_{ₑ}); or a combination of J₀_{ₑ} and the emitter sheet resistance, wherein J₀_{ₑ} is determined based on the emitter sheet resistance, the minority carrier lifetime and the wafer thickness.

30. The apparatus of claim 23, wherein the at least one of the I-V parameters includes short-circuit current (I_{SC}) or short-circuit current density (J_{SC}), and wherein the one or more processors are configured to determine I_{SC} or J_{SC} based on saturation current density (J₀), the emitter sheet resistance, and wafer resistivity, wherein J₀ is determined based on the wafer resistivity and the minority carrier lifetime, and wherein wafer resistivity is either measured directly or determined based on emitter sheet resistance and overall wafer resistivity.

31. The apparatus of claim 23, wherein the at least one of the I-V parameters includes fill factor (FF), and wherein the one or more processors are configured to determine FF based on either: the emitter sheet resistance; or a combination of the emitter sheet resistance with saturation current density (J₀), or emitter saturation current density (J₀_{ₑ}), wherein J₀ is determined based on the wafer resistivity and the minority carrier lifetime, and J₀_{ₑ} is determined based on the emitter sheet resistance and the minority carrier lifetime.

32. The apparatus of claim 21, wherein the one or more measurement devices are provided in-line with a manufacturing process for providing the photovoltaic cells.

33. The apparatus of claim 21, wherein the one or more measurement devices consist of one of the following arrangements: one or more infrared transmissivity or infrared reflectometry (IRR) measurement devices, one or more wafer thickness gauges and one or more QSSPC devices incorporating an eddy current probe; one or more IRR devices, one or more wafer thickness gauges, one or more QSSPC devices and one or more separate eddy current probes; one or more IRR devices, one or more wafer thickness gauges, one or more photoluminescence (PL) measurement devices and one or more eddy current probes; or one or more microwave detected photoconductivity (MDP) devices, one or more wafer thickness gauges, one or more eddy current probes, and one or more IRR devices.

34. An apparatus for estimating an effect of variations of wafer properties on operating parameters of photovoltaic cells, the apparatus comprising:
one or more measurement devices configured to obtain measurements of one or more properties of a wafer during manufacture of the wafer into a photovoltaic cell;
one or more processors operatively coupled to the one or more measurement devices and configured to: generate estimates of eventual current and voltage (I-V) parameters of the photovoltaic cell, the estimates generated based at least in part on the obtained measurements;
a database, wherein the one or more processors are configured to store, in the database, said estimates of I-V parameters along with an identifier of the wafer;
an I-V cell tester configured, following one or more manufacturing process steps performed after obtaining said measurements, to measure I-V parameters of the photovoltaic cell manufactured from the wafer,
and wherein the one or more processors are configured, upon determining a deviation, of said measured I-V parameters for the wafer or for a collection of wafers including the wafer, from an expected value or statistical distribution, to:
retrieve information related to the wafer or the collection of wafers from the database, said information including said estimates of I-V parameters, said measurements, or a combination thereof;
analyze the retrieved information in association with stored data characterizing a set of known manufacturing faults;
determine, based on said analysis, one or more potential manufacturing faults which are relatively more likely to have occurred; and
output an indication of said one or more potential manufacturing faults.

35. An apparatus for estimating an effect of variations of wafer properties on operating parameters of photovoltaic cells, the apparatus comprising:
one or more measurement devices configured to obtain observed values of one or more properties of each of a set of wafers during manufacture of each of the set of wafers into a corresponding photovoltaic cell;
one or more processors operatively coupled to the one or more measurement devices and configured to: generate estimates of eventual current and voltage (I-V) parameters of the photovoltaic cells, the estimates generated based at least in part on the observed values, the estimates generated using an estimation procedure;
an I-V cell tester configured, following one or more manufacturing process steps performed after obtaining said measurements, to measure I-V parameters of the photovoltaic cells manufactured from the wafers,
wherein the one or more processors are further configured to:
compute, for each of the photovoltaic cells, an imputed value, the imputed value being determined such that, when the imputed value is input to said estimation procedure, the estimation procedure outputs a match to said measured I-V parameters; and
adjust the estimation procedure based at least in part on a comparison of said observed values and said imputed values.

36. The apparatus of claim 35, wherein said properties comprise one or more of: emitter sheet resistance, minority carrier lifetime, thickness, and wafer resistivity.

37. The apparatus of claim 35, wherein the comparison of said observed values and said imputed values comprises determining error vectors each being equal to a vector difference between one of said observed values and a corresponding one of said imputed values.

38. The apparatus of claim 37, wherein the estimation procedure is adjusted based on the error vectors.

39. The apparatus of claim 35, wherein the estimation procedure is adjusted based on a cumulative representation of multiple error vectors, each error vector being equal to a vector difference between one of said observed values and a corresponding one of said imputed values.
